(19) United States
(12) Patent Application Publication
(10) Pub. No.: US 2007/0114428 A1
(43) Pub. Date: May 24, 2007

(54) Radiation Image Capturing Condition Correction Apparatus and Radiation Image Capturing Condition Correction Method

(75) Inventors: Shinji YOSHINO, Osaka (JP); Tsuyoshi TOJO, Osaka (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 11/560,017

(22) Filed: Nov. 15, 2006

(30) Foreign Application Priority Data
Nov. 18, 2005 (JP) JP 2005-334805

(51) Int. Cl. G01T 1/24; H01L 27/146

(52) U.S. Cl. 250/370.09

(57) ABSTRACT

A radiation image capturing condition correction apparatus for use with a) an image-capturing unit which captures a radiation image of a predetermined imaging subject; and b) a radiation generating unit which generates radiation, said radiation image capturing condition correction apparatus comprising: a measuring unit which measures an amount of physical displacement of said radiation generating unit; and a position correction unit for generating a correction value which is used for correcting a position at which said image-capturing unit captures said radiation image.

### BACKGROUND OF THE INVENTION

1. Field of the Invention

The present invention relates to a radiation image capturing apparatus such as an inspection machine for performing transmission inspection of the inside of an object, or an X-ray CT apparatus or an X-ray tomography apparatus for comprehending a three-dimensional contour and to a radiation image capturing method. More particularly, the present invention relates to a radiation image capturing condition correction apparatus and a radiation image capturing condition correction method for suppressing deterioration in the accuracy and the resolution, due to image blurs and image distortion caused by radiation-source displacement that changes with irradiation time.

2. Related Art of the Invention

A technique, utilizing radiations such as X-rays, for capturing a two-dimensional or a three-dimensional radiation image has been widely employed to inspect the inner structures of products. In the case of an X-ray, by utilizing an X-ray source having a minute X-ray radiant point, making X-rays pass through an imaging subject, and capturing the obtained X-rays on an image capturing plane, an image is obtained.

FIG. 8 is an example of a conventional image capturing apparatus utilizing X-rays (e.g., refer to Japanese Patent Application Laid-Open No. 2002-5854). In FIG. 8, Reference Numeral 71 denotes an X-ray radiant unit; Reference Numeral 72, an emitted X-ray; Reference Numeral 73, an imaging subject to be image-captured; Reference Numeral 74, an X-ray image-capturing tube; Reference Numeral 75, an captured-image processing apparatus; and Reference Numeral 76, a display monitor for a captured image. X-rays advance in a linear radiation fashion from the radiation source 71a on the X-ray radiant unit 71; the imaging subject 73 situated in the half way attenuates the X-rays; and part of the X-rays reach the X-ray image-capturing tube 74 and form an image.

In capturing the radiation image, a problem called “radiation-source displacement” has been known. As described later, in the case of an X-ray, an X-ray source, in general, generates X-rays as the secondary emission caused by the collision of an electron beam, which is emitted from a filament contained in a metal case, with a specific portion inside the case.

During image capturing, the radiation source is displaced minutely, thereby making an image being captured to be displaced on the image capturing plane; as a result, the position of the imaging subject is displaced from the position where the subject ought to be, i.e., the problem called “radiation-source displacement” is posed.

FIG. 9 is a diagram, in which the vicinity of the X-ray radiant unit 71 is magnified, for explaining that the effect on the position of the imaging subject 73 depending on the difference of the position of the radiant points. Reference Numeral 81 denotes an X-ray radiant unit as a filament; Reference Numerals 82 and 83 denote emitted X-rays. As described above, in the X-ray radiant unit 81, an electron beam collides with a metal body called “target”, whereby the radiation source 81a emits X-rays; however, as the emission period becomes long, the heating and the like of the target and the X-ray radiant unit 81 cause the radiation source 81a to be displaced minutely. Accordingly, the path of the emitted X-ray shifts with time from the emitted X-ray 82 to the emitted X-ray 83; therefore, even though the same imaging subject 73 is image-captured by the same capturing system, X-rays that pass through the subject 73 and reach the X-ray image-capturing tube 74 differ from one another. As a result, as illustrated in FIG. 10, a position 84 of the imaging subject 73 on a screen 90 of the X-ray image-capturing tube 74 changes with time and shifts to a position 85; therefore, with respect to the position of the subject 73, the same result is not always acquired.

In order to cope with the foregoing problem, an image capturing apparatus is disclosed in which, by focusing attention on the correlation between the radiation-source displacement and the radiation-source temperature and providing a focus-position temperature performance obtaining unit so as to preliminarily measure and store the changing performances of the radiation-source temperature and the focus position, an image is rerendered when an actual scan is performed, by utilizing correction values obtained from the performances (e.g., refer to Japanese Patent Publication Laid-Open No. 1995-116157).

FIG. 11 is a diagram illustrating an X-ray CT image-capturing apparatus provided with a conventional radiation-source-shift correction function disclosed in Japanese Patent Publication Laid-Open No. 1995-116157. An X-ray CT image-capturing apparatus 200 in FIG. 11 includes a scanner unit 201, an X-ray tube drive unit 203, a preprocessing unit 206, an image rerendering unit 207, a CRT 208, a focus-position temperature performance obtaining unit 209, a focus-position temperature performance storing unit 210, and a focus error value providing unit 211. The scanner unit 201 has an X-ray tube 202 and a detector 205. The X-ray tube 202 is driven by the X-ray tube drive unit 203. The X-ray tube drive unit 203 has an X-ray tube temperature obtaining unit 204 that computes through simulation the temperature of the X-ray tube 202, in order to control the scanning plan, based on the temperature of the X-ray tube 202. The detector 205 collects raw data and transmits the raw data to the preprocessing unit 206. The preprocessing unit 206 applies various kinds of preprocessing items to the raw data and transmits the preprocessed raw data to the image rerendering unit 207. The image rerendering unit 207 rerenders an image, based on the preprocessed raw data; the CRT 208 displays the image. The image rerendering unit 207 has a focus error correction unit which, when a focus error value δ is given, rerenders an image, taking the focus error value δ into account.

By measuring the temperature T1 and the focus position S1, the temperature T2 and the focus position S2, and the temperature T3 and the focus position S3, of the X-ray tube 202, when the X-ray tube 202 has a low temperature, when the X-ray tube 202 has an intermediate temperature, and when the X-ray tube 202 has a high temperature, respectively, the focus-position temperature performance obtaining unit 209 obtains the focus position S vs. temperature T performance of the X-ray tube 202. The focus-position temperature performance storing unit 210 stores the focus-position temperature performance obtained by the focus-position temperature performance obtaining unit 209. Based on the stored focus-position temperature performance, the focus error value providing unit 211 obtains a focus error value δx corresponding to the temperature Tx at which an actual scan is performed, and as the focus error value δ, provides the focus error value δx to the focus error correction unit of the image rerendering unit 207.

As described heretofore, the X-ray CT image-capturing apparatus performs a focus error correction utilizing relationship between the temperature of the X-ray CT and the focus position.

However, the above-mentioned conventional radiation-source correction apparatus, which performs the correction based on the correlation between the temperature and the focus position, has the following problem: A phase difference exists between the temperature to be detected and the focus position, and the X-ray tube has a structure having large volume; therefore, even though the temperature of an arbitrary position on the X-ray tube is measured, the temperature of the measurement position and the displacement of the focus position do not correspond to each other on a one-to-one basis, whereby it is difficult to carry out high-accuracy anticipation of the displacement amount.

### SUMMARY OF THE INVENTION

The present invention has been implemented in order to solve the conventional problem; the object of the present invention is to provide a radiation-image capturing condition correction apparatus and a radiation-image capturing condition correction method, which can readily realize high-accuracy correction for a radiation-source shift, and a radiation-image capturing apparatus utilizing that correction apparatus and that correction method.

The 1^{st} aspect of the present invention is a radiation image capturing condition correction apparatus for use with a) an image-capturing unit which captures a radiation image of a predetermined imaging subject; and b) a radiation generating unit which generates radiation, said radiation image capturing condition correction apparatus comprising:

a measuring unit which measures an amount of physical displacement of said radiation generating unit; and

a position correction unit for generating a correction value which is used for correcting a position at which said image-capturing unit captures said radiation image.

The 2^{nd} aspect of the present invention is the radiation image capturing condition correction apparatus according to the 1^{st} aspect of the present invention, wherein, the position correction unit, based on the generated correction value, performs correction in such a way that the relative positional relationships, among the radiation generating unit, the predetermined imaging subject, and the image-capturing unit, which exist when the radiation generating unit is at the predetermined position is maintained.

The 3^{rd} aspect of the present invention is the radiation image capturing condition correction apparatus according to the 2^{nd} aspect of the present invention, wherein, as the correction, the position correction unit moves the radiation generating unit.

The 4^{th} aspect of the present invention is the radiation image capturing condition correction apparatus according to the 2^{nd} aspect of the present invention, wherein, as the correction, the position correction unit moves the imaging subject and the image-capturing unit.

The 5^{th} aspect of the present invention is the radiation image capturing condition correction apparatus according to the 2^{nd} aspect of the present invention, wherein, as the correction, the position correction unit moves each of the radiation generating unit, the imaging subject, and the image-capturing unit.

The 6^{th} aspect of the present invention is the radiation image capturing condition correction apparatus according to the 2^{nd} aspect of the present invention, wherein, as the correction, the position correction unit returns the radiation generating unit to the predetermined position.

The 7^{th} aspect of the present invention is the radiation image capturing condition correction apparatus according to the 2^{nd} aspect of the present invention, wherein the one direction is a direction along a line perpendicular to an image capturing plane for the radiation image and the position correction unit performs correction operation in the one direction.

The 8^{th} aspect of the present invention is the radiation image capturing condition correction apparatus according to the 7^{th} aspect of the present invention, wherein the physical displacement amount is measured in one direction or in two directions, which are perpendicular to each other, on the image capturing plane, and the position correction unit performs correction operation in the one direction or in the two directions.

The 9^{th} aspect of the present invention is the radiation image capturing condition correction apparatus according to the 1^{st} aspect of the present invention, wherein, as the radiation, any one of an X-ray, an α-ray, a β-ray, a γ-ray, and a heavy-ion ray is utilized.

The 10^{th} aspect of the present invention is a radiation image capturing apparatus comprising:

a radiation generating unit which generates radiations;

an imaging subject arrangement unit on which a predetermined imaging subject is arranged;

an image-capturing unit having an image capturing plane on which a radiation image, which is image-captured by means of the radiations, of the imaging subject is formed; and

the radiation image capturing condition correction apparatus according to the 1^{st} aspect of the present invention.

The 11^{th} aspect of the present invention is a radiation image capturing condition correction apparatus comprising:

a measuring unit which, in capturing on an image-capturing unit a radiation image of a predetermined imaging subject, measures an amount of physical displacement, of a radiation generating unit which generates radiations, from a predetermined position in at least one direction; and

a data correction unit which corrects data on the radiation image, based on the physical displacement amount and the relative positional relationships, among the radiation generating unit, the imaging subject, and the image-capturing unit, at the moment when the radiation generating unit has been at the predetermined position.

The 12^{th} aspect of the present invention is the radiation image capturing condition correction apparatus according to the 11^{th} aspect of the present invention, wherein the data correction unit utilizes, as the data on the radiation image, a predetermined amount corresponding to the physical displacement amount and performs correction in which the position of a coordinate origin defined on a detection plane of the image-capturing unit is moved by the predetermined amount.

The 13^{th} aspect of the present invention is the radiation image capturing condition correction apparatus according to the 11^{th} aspect of the present invention, wherein the data correction unit utilizes, as the data on the radiation image, a predetermined amount corresponding to the physical displacement amount and performs correction in which a detection position of the imaging subject on a detection plane of the image-capturing unit is moved by the predetermined amount.

The 14^{th} aspect of the present invention is the radiation image capturing condition correction apparatus according to the 11^{th} aspect of the present invention, wherein the one direction is a direction along a line perpendicular to an image capturing plane for the radiation image and the data correction unit performs correction operation in the one direction.

The 15^{th} aspect of the present invention is the radiation image capturing condition correction apparatus according to the 14^{th} aspect of the present invention, wherein the physical displacement amount is measured in one direction or in two directions, which are perpendicular to each other, on the image capturing plane, and the data correction unit performs correction operation in the one direction or in the two directions.

The 16^{th} aspect of the present invention is the radiation image capturing condition correction apparatus according to the 11^{th} aspect of the present invention, wherein, as the radiation, any one of an X-ray, an α-ray, a β-ray, a γ-ray, and a heavy-ion ray is utilized.

The 17^{th} aspect of the present invention is a radiation image capturing apparatus comprising:

a radiation generating unit which generates radiations;

an imaging subject arrangement unit on which a predetermined imaging subject is arranged;

an image-capturing unit having an image capturing plane on which a radiation image, which is image-captured by means of the radiations, of the imaging subject is formed; and

the radiation image capturing condition correction apparatus according to the 11^{th} aspect of the present invention.

The 18^{th} aspect of the present invention is a radiation image capturing condition correction method for use with a) an image-capturing unit which captures a radiation image of a predetermined imaging subject; and b) a radiation generating unit which generates radiation, said radiation image capturing condition correction apparatus, comprising:

measuring an amount of physical displacement of said radiation generating unit; and

generating a correction value which is used for correcting a position at which said image-capturing unit captures said radiation image.

The 19^{th} aspect of the present invention is the radiation image capturing condition correction method according to the 18^{th} aspect of the present invention, further comprising, performing correction, based on the generated correction value, in such a way that the relative positional relationships, among the radiation generating unit, the predetermined imaging subject, and the image-capturing unit, which exist when the radiation generating unit is at the predetermined position is maintained.

The 20^{th} aspect of the present invention is the radiation image capturing condition correction method according to the 18^{th} aspect of the present invention, wherein, as the radiation, any one of an X-ray, an α-ray, a β-ray, a γ-ray, and a heavy-ion ray is utilized.

The 21^{st} aspect of the present invention is a radiation image capturing condition correction method comprising:

measuring an amount of physical displacement of a radiation generating unit which generates radiations, from a predetermined position in at least one direction, in capturing on an image-capturing unit a radiation image of a predetermined imaging subject; and

correcting data on the radiation image, based on the physical displacement amount and the relative positional relationships, among the radiation generating unit, the imaging subject, and the image-capturing unit, at the moment when the radiation generating unit has been at the predetermined position.

The 22^{nd} aspect of the present invention is the radiation image capturing condition correction method according to the 21^{st} aspect of the present invention, wherein, as the radiation, any one of an X-ray, an α-ray, a β-ray, a γ-ray, and a heavy-ion ray is utilized.

The 23^{rd} aspect of the present invention is a computer-processable storage medium in which a program is stored, the program making a computer function as a data correction unit, of the radiation image capturing condition correction apparatus according to the 11^{th} aspect of the present invention, that corrects data on the radiation image, based on the physical displacement amount and the relative positional relationships, among the radiation generating unit, the imaging subject, and the image-capturing unit, at the moment when the radiation generating unit has been at the predetermined position.

The present invention makes it possible that a radiation-image capturing condition correction apparatus and a radiation-image capturing condition correction method that can readily realize a high-accuracy radiation-source-shift correction are put into practice. Inconsequence, a high-magnification and high-resolution radiation image capturing apparatus with reduced aliasings and artifacts can be realized.

### BRIEF DESCRIPTION OF THE DRAWINGS

FIG. 1 is a diagram illustrating the basic structure of an X-ray CT image-capturing apparatus according to Embodiment 1 of the present invention;

FIG. 2(A) is a schematic diagram illustrating the inner structure of an X-ray radiant unit 1 of an X-ray CT image-capturing apparatus according to Embodiment 1 of the present invention;

FIG. 2(B) is a plan view of the X-ray radiant unit 1;

FIG. 3 is a flowchart illustrating the correction procedure of a correction apparatus in an X-ray CT image-capturing apparatus according to Embodiment 1 of the present invention;

FIG. 4 is a diagram illustrating the structure of another example of an X-ray CT image-capturing apparatus according to Embodiment 1 of the present invention;

FIG. 5 is a diagram illustrating the basic structure of an X-ray CT image-capturing apparatus according to Embodiment 2 of the present invention;

FIG. 6 is a flowchart illustrating the correction procedure of a correction apparatus in an X-ray CT image-capturing apparatus according to Embodiment 2 of the present invention;

FIG. 7(A) is a chart for explaining the correction of a correction apparatus in an X-ray CT image-capturing apparatus according to Embodiment 2 of the present invention;

FIG. 7(B) is a chart for explaining the correction of a correction apparatus in an X-ray CT image-capturing apparatus according to Embodiment 2 of the present invention;

FIG. 7(C) is a chart for explaining the correction of a correction apparatus in an X-ray CT image-capturing apparatus according to Embodiment 2 of the present invention;

FIG. 7(D) is a chart for explaining the correction of a correction apparatus in an X-ray CT image-capturing apparatus according to Embodiment 2 of the present invention;

FIG. 8 is a diagram illustrating the configuration of an X-ray image capturing apparatus according to a conventional technique;

FIG. 9 is a diagram for explaining a radiation-source shift;

FIG. 10 is a diagram for explaining an effect of a radiation-source shift; and

FIG. 11 is a diagram for explaining a radiation-source-shift correction apparatus according to a conventional technique.

### DESCRIPTION OF SYMBOLS

1 X-Ray Radiant Unit
2 Table
3 Detector
4 Image Reception/Processing Apparatus
5 Image-Capturing Controller
6 Table Moving Mechanism
7 Detector Moving Mechanism
8 Image Display Apparatus
9a to 9c Laser Displacement Gauge
10 Imaging Subject
11 X-Ray Radiant Unit Moving Mechanism

### PREFERRED EMBODIMENTS OF THE INVENTION

Embodiments of the present invention will be explained below with reference to the accompanying drawings.

### Embodiment 1

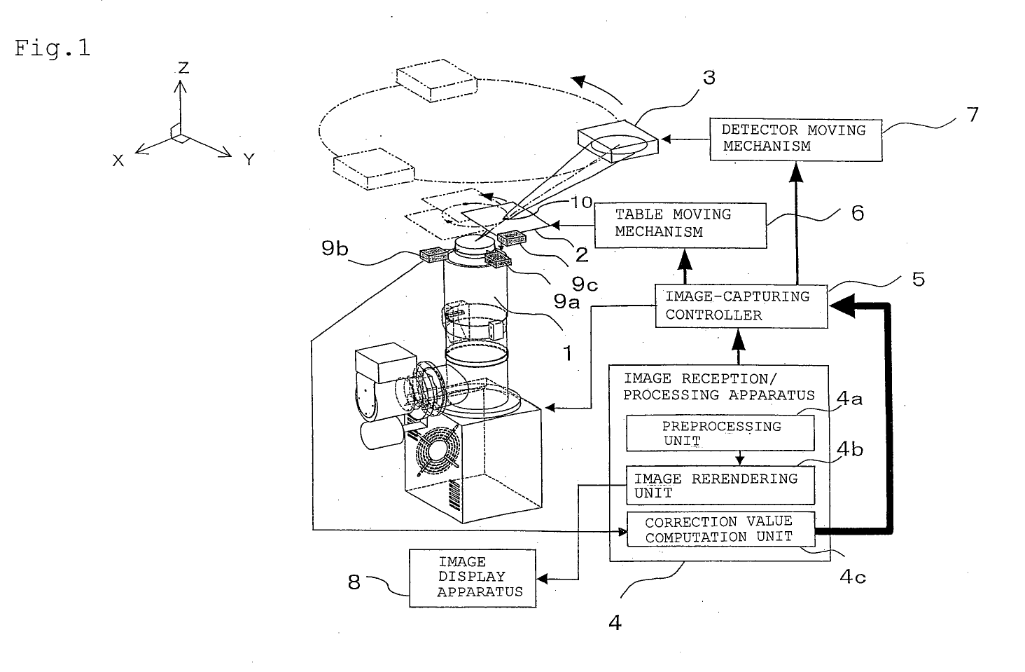

FIG. 1 is a diagram illustrating the basic structure of an X-ray CT image-capturing apparatus according to Embodiment 1 of the present invention.

In FIG. 1, an X-ray CT image-capturing apparatus according to Embodiment 1 is configured of an X-ray radiant unit 1 for generating X-rays, a table 2 for moving an imaging subject 10, a detector 3 for receiving X-rays that have passed through the imaging subject 10 and converting the received X-rays into an image, an image reception/processing apparatus 4 for receiving and rerendering the converted image, an image-capturing controller 5, at able moving mechanism 6, a detector moving mechanism 7, an image display apparatus 8, and laser displacement gauges 9a to 9c.

The table moving mechanism 6 is a unit for moving the imaging subject 10 on a plane perpendicular to the line that connects the X-ray radiant unit 1 and the detector 3. The detector moving mechanism 7 is a unit for moving the detector 3 along the line that connects the X-ray radiant unit 1 and the detector 3 or on a plane perpendicular to that line. The basic operation is as follows. While the table 2 and the detector 3 are revolving around the cylindrical rotation center, of the X-ray radiant unit 1, as an axis, the detector 3 performs image capturing. The captured image is preprocessed in a preprocessing unit 4a and rerendered as a tomographic image in an image rerendering unit 4b. Accordingly, it is made possible to perform without rotating the imaging subject 10 slanted-direction image capturing, which is required for rerendering of a CT image.

In Embodiment 1, the laser displacement gauges 9a to 9c are utilized as units for measuring the displacement of the x-ray radiant unit 1. The laser displacement gauges 9a, 9b, and 9c are the units for measuring the displacement amounts, of the front end of the X-ray radiant unit 1, in the x, y, and z directions, respectively. The results of the displacement measurement through the laser displacement gauges 9a˜9c are inputted to a correction value computation unit 4c. After the correction value computation unit 4c performs computation of a correction value, the image capturing position for a transmission image is corrected, by correcting an instruction to the image-capturing controller 5, based on the correction value. In addition, the x direction signifies a direction parallel to the main plane of the detector 3; the y direction signifies a direction that is parallel to the main plane of the detector 3 and perpendicular to the x direction. The z direction signifies a direction perpendicular to the main plane of the detector 3; in FIG. 1, the z direction substantially coincides with the center axis of the cylindrical outer contour of the X-ray radiant unit 1.

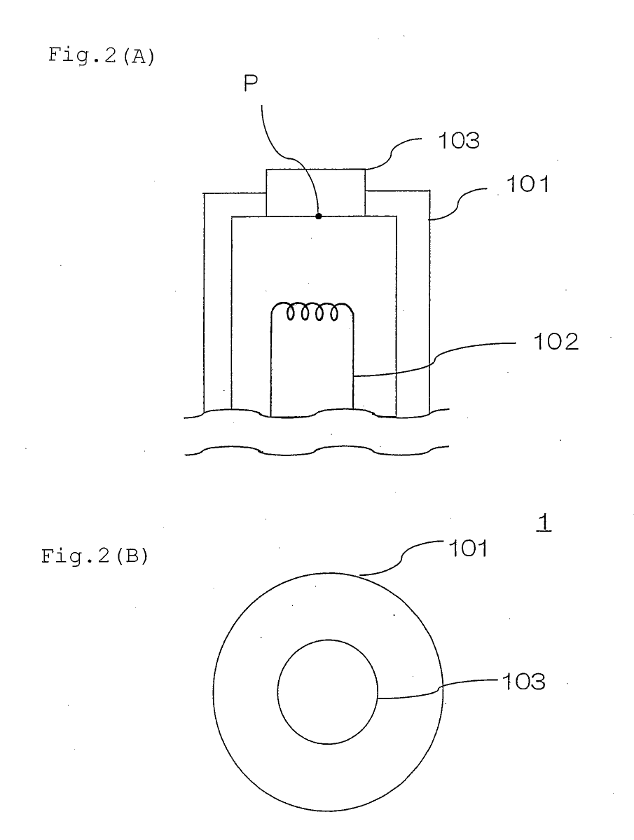

FIG. 2(A) is schematic diagram illustrating the inner structure of the X-ray radiant unit 1; FIG. 2(B) is a plan view illustrating the inner structure of the X-ray radiant unit 1.

As illustrated in FIGS. 2(A) and 2(B), the X-ray radiant unit 1 has a case 101 that forms the approximately cylindrical outer contour thereof, a filament 102 that is situated inside the case 101 and generates electron beams, and a radiation-source body 103 that is situated at the canopy portion of the case 101 and functions as a plane with which an electron beam generated from the filament 102 collides and from which X-rays are generated. In addition, the case 101 is made of metal such as iron; the radiation-source body 103 is made of tungsten.

In the foregoing configuration, the X-ray radiant unit 1 corresponds to a radiation generating unit as termed in the present invention; the laser displacement gauges 9a to 9c correspond to measuring units as termed in the present invention. The correction value computation unit 4c, the image-capturing controller 5, the table moving mechanism 6, and the detector moving mechanism 7 correspond to position correction units as termed in the present invention and configure a radiation image capturing condition correction apparatus as termed in the present invention.

The X-ray CT image-capturing apparatus is an example of a radiation image capturing apparatus as termed in the present invention; the table 2 corresponds to an imaging subject arrangement unit as termed in the present invention; the detector 3 corresponds to an image-capturing unit as termed in the present invention.

The operation of an X-ray CT image capturing apparatus, having the foregoing configuration, according to Embodiment 1 of the present invention will be explained; through the explanation of the operation, an embodiment of a radiation image capturing condition correction method as termed in the present invention will be explained.

The principle of the present invention will be explained first. Radiation-source-shift correction through conventional technologies takes into account, as a cause of the radiation-source shift, the effects of heating of the filament 102, the case 101, and the like inside the X-ray radiant unit 1 illustrated in FIG. 2; however, the correction has a significant disadvantage that, due to each the structure having large volume of the case 101 and the radiation-source body 103, it is difficult to comprehend which portion of the X-ray radiant unit 1 shows temperature change that corresponds most to the radiation-source shift, whereby the anticipation of the direction and the extent of correction is difficult to perform actually.

In contrast, the present invention is characterized by focusing attention on the relationship between the change in the contour of the X-ray radiant unit 1 and the radiation-source shift, caused by the temperature change in the case 101 and the like, due to the lighting of the filament 102. In other words, due to the heating of the filament 102, case 101 and the radiation-source body 103 both of which are made of metal expand; because the electron-beam collision position P, inside the X-ray radiant unit 1, from which X-rays are generated are situated on the radiation-source body 103, the collision position P also shifts by the expansion amounts of the case 101 and the radiation-source body 103.

The arrangement of a radiation image formed on the image capturing plane of the detector 3, the X-ray radiant unit 1, the table 2, and the detector 3 is fixed; therefore, when a positional change in any portion is produced, it is possible to geometrically detect the positional change as a change in any one of the rest portions. Accordingly, as long as the table 2 and the detector 3 are fixed, it is conceivable that the radiation image detected by the detector 3 is shifted, this shift is occured as the shift of the X-ray radiation source.

Thus, by measuring an alternation of the physical contour or the placement of the outer contour of the X-ray radiant unit 1 (especially the vicinity of the radiation-source body 103 that actually generates) in each direction of X, Y and Z axis from the state when the measure starts, if the alternation (hereafter referred to as a “physical displacement amount”) is produced, the physical displacement amount is considered as the shift of the X-ray radiation source. And in accordance with the direction and the magnitude of the physical displacement amount, the positional relationships among the radiation source, the imaging subject, and the detector are corrected. The metal expansion in the vicinity of the radiation-source body 103 can be considered to be isotropic, compared to the temperature distribution.

Accordingly, accurate comprehension of the direction and the magnitude of a radiation-source shift is enabled, whereby high-accuracy radiation-source correction can be performed.

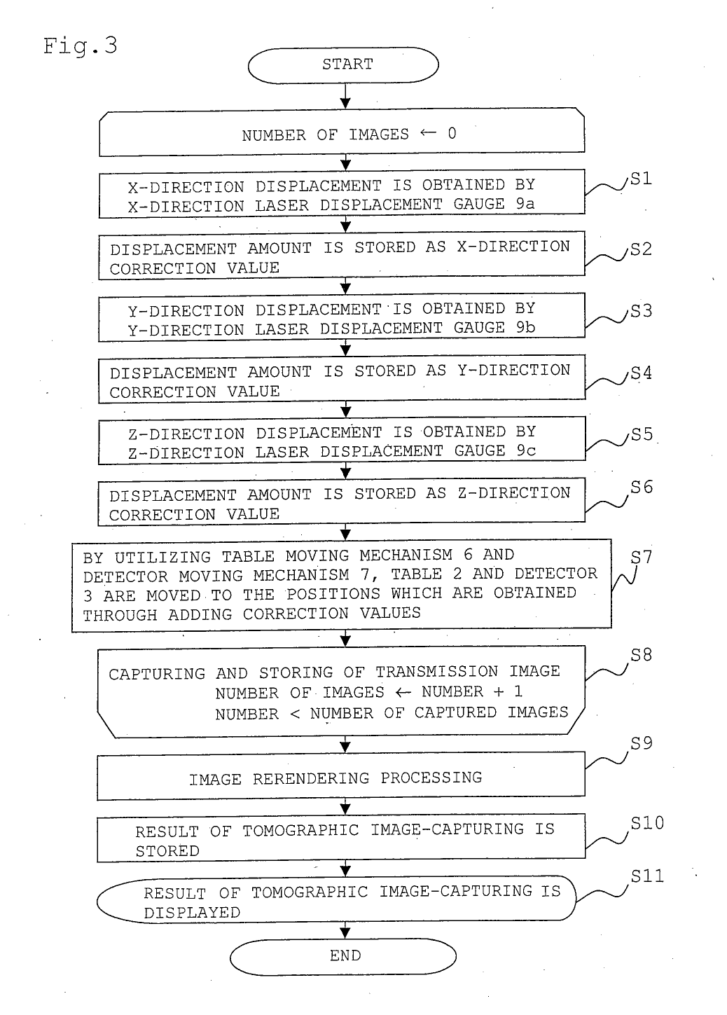

Embodiment 1 will be explained in detail below with reference to a flowchart in FIG. 3. FIG. 3 illustrates a procedure of correction according to Embodiment 1. In the first place, as a predetermined position, the position, of the front end of the X-ray radiant unit 1, under specific conditions (temperature, humidity, and the like) is measured by the laser displacement gauges 9a to 9c and set up as a reference point.

Next, in Step S1, the x-direction displacement, of the front end of the X-ray radiant unit 1, with respect to the reference point is measured by the laser displacement gauge 9a. Next, in Step S2, the obtained displacement amount is stored as an x-direction correction value Δx. In Step S3, the y-direction displacement, of the front end of the X-ray radiant unit 1, with respect to the reference point is measured by the laser displacement gauge 9b. In Step S4, the obtained displacement amount is stored as a y-direction correction value Δy. Similarly, in Step S5, the z-direction displacement, of the front end of the X-ray radiant unit 1, with respect to the reference point is measured by the laser displacement gauge 9c. In Step S6, the obtained displacement amount is stored as a z-direction correction value Δz.

Next, in Step S7, by, through the image-capturing controller 5, utilizing the table moving mechanism 6 and the detector moving mechanism 7, the table 2 and the detector 3 are moved to the positions, which are obtained through computation, corresponding to the respective positions of the table 2 and the detector 3 at the moment when the front end of the X-ray radiant unit 1 was situated at the reference point. In this situation, it is assumed that a correction value computed by the correction value computation unit 4c, based on the stored correction values Δx, Δy, and Δz, is a predetermined amount to be required to move the table 2 and the detector 3.

Accordingly, the movement, in accordance with the correction values, of the able 2 and the detector 3 returns the relative positional relationships among the radiation source inside the X-ray radiant unit 1, the table 2, and the detector 3 in the image capturing apparatus to the relative positional relationships among the respective elements at the moment when the front end of the X-ray radiant unit 1 was situated at the reference point. In this regard, however, the arrangement positions of the table 2 and the detector 3 in the X-ray CT image-capturing apparatus are changed.

In Step S8, by, through the image-capturing controller 5, controlling the X-ray radiant unit 1 and the detector 3, a transmission image is captured and stored.

The Step S8 is repeatedly performed for a certain number of images necessary for image rerendering. Additionally, in Step S9, after being processed by the preprocessing unit 4a, the stored image is converted by the image rerendering unit 4b into a tomographic image; in Step S10, the resultant image is stored and, in Step S11, outputted to the image display apparatus 8.

As discussed heretofore, according to Embodiment 1, by measuring the physical displacement amount of the front end of the X-ray radiant unit 1, the change in the radiation-source position can accurately be anticipated and corrected. Accordingly, by preliminarily removing the effect of the radiation-source position that changes with time, a clear and high-resolution tomographic image can be obtained that has no blur such as an aliasing or an artifact.

In addition, in Embodiment 1, a tomography is realized by a method in which the imaging subject 10 is not rotated; however, the X-ray CT image-capturing apparatus may be configured in such a way that a tomography is realized by a method in which the imaging subject 10 is rotated. Moreover, as a unit which measures the physical displacement amount of the front end of the X-ray radiant unit 1, the laser displacement gauges 9a to 9c are utilized; however, the measuring unit of the present invention is not limited thereto; for example, contact-type displacement gauges may be utilized.

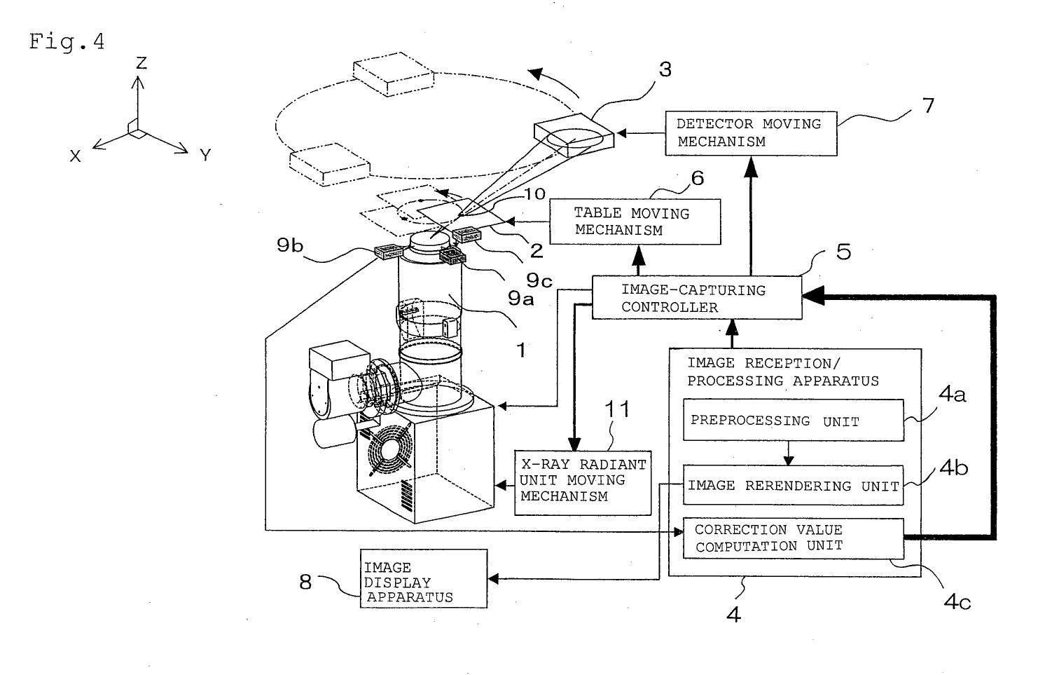

Still moreover, in the foregoing explanation, correction is performed, by, through the table moving mechanism 6 and the detector moving mechanism 7, moving by a predetermined amount the table 2 and the detector 3; however, as illustrated in FIG. 4, the X-ray CT image-capturing apparatus may be configured in such a way as to include an X-ray radiant unit moving mechanism 11 for moving the X-ray radiant unit 1. In this case, with the table 2 and the detector 3 fixed, correction is performed by, as Step S7, moving the X-ray radiant unit 1 in such a way that the X-ray radiant unit 1 returns by the amount of the measured physical displacement and along the direction of the measured physical displacement. Also in this case, in the image capturing apparatus at the moment after correction has been performed, the relative positional relationships among the radiation source inside the X-ray radiant unit 1, the table 2, and the detector 3 coincide with the relative positional relationships among the foregoing elements at the moment when the front end of the X-ray radiant unit 1 was situated at the reference point, and the positional relationships among the respective portions inside the X-ray CT image-capturing apparatus are also restored.

Furthermore, the X-ray CT image-capturing apparatus according to the present invention may be configured in such a way that the table moving mechanism 6, the detector moving mechanism 7, and the X-ray radiant unit moving mechanism 11 are all provided, and correction is performed by moving the table 2 and the detector 3 by a predetermined amount and, in response to the movement, returning the X-ray radiant unit 1 by the amount corresponding to the traveling amount of the table 2 and the detector 3. In this case, the relative positional relationships among the respective portions inside the X-ray CT image-capturing apparatus differ from the original ones; however, in the image capturing apparatus at the moment after correction has been performed, the relative positional relationships among the radiation source inside the X-ray radiant unit 1, the table 2, and the detector 3 coincide with the relative positional relationships among the foregoing elements at the moment when the front end of the X-ray radiant unit 1 was situated at the reference point. The foregoing configuration is effective in the case where the respective traveling ranges of the table moving mechanism 6, the detector moving mechanism 7, and the X-ray radiant unit moving mechanism 11 are restricted.

In summary, the present invention has only to be configured in such a way that the condition in which the X-ray radiant unit 1 is situated at a predetermined position where a user consider that correction through radiation-source shift is not required is assumed to be the reference condition, and the X-ray radiant unit 1, the imaging subject 10 placed on the table 2, and the detector 3 move so that the relative relationships, under the reference condition, among the respective elements can be maintained, whereby correction is performed. Thus, the present invention is not limited by an actual moving procedure or moving subjects. In addition, the method of determining the predetermined position may arbitrarily be specified by a user, in accordance with the utilization condition of the apparatus.

### Embodiment 2

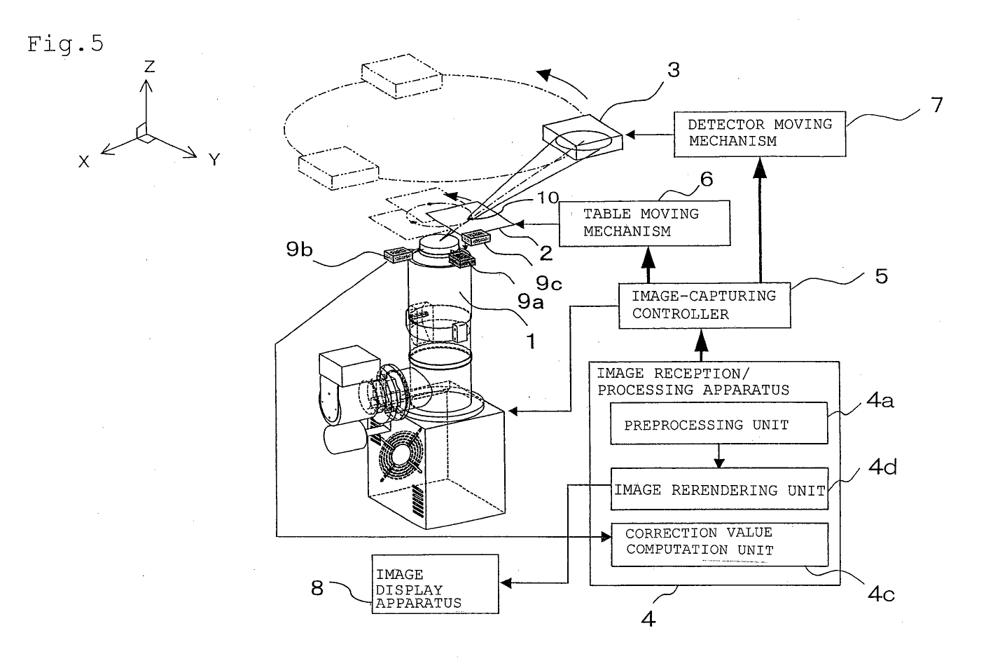

FIG. 5 is a diagram illustrating the basic structure of an X-ray CT image-capturing apparatus according to Embodiment 2 of the present invention. In FIG. 5, constituent elements identical or corresponding to those in FIG. 1 have identical reference characters, and explanation therefor will be omitted. The X-ray CT image-capturing apparatus according to Embodiment 2 differs from that according to Embodiment 1, in that the table moving mechanism 6 and the detector moving mechanism 7 each do not perform correction operation based on a correction-value input, but perform only moving operation for CT image capturing, and the image rerendering unit 4d performs processing operation based on a correction value input from the correction value computation unit 4c. In addition, the image rerendering unit 4d corresponds to a data correction unit as termed in the present invention.

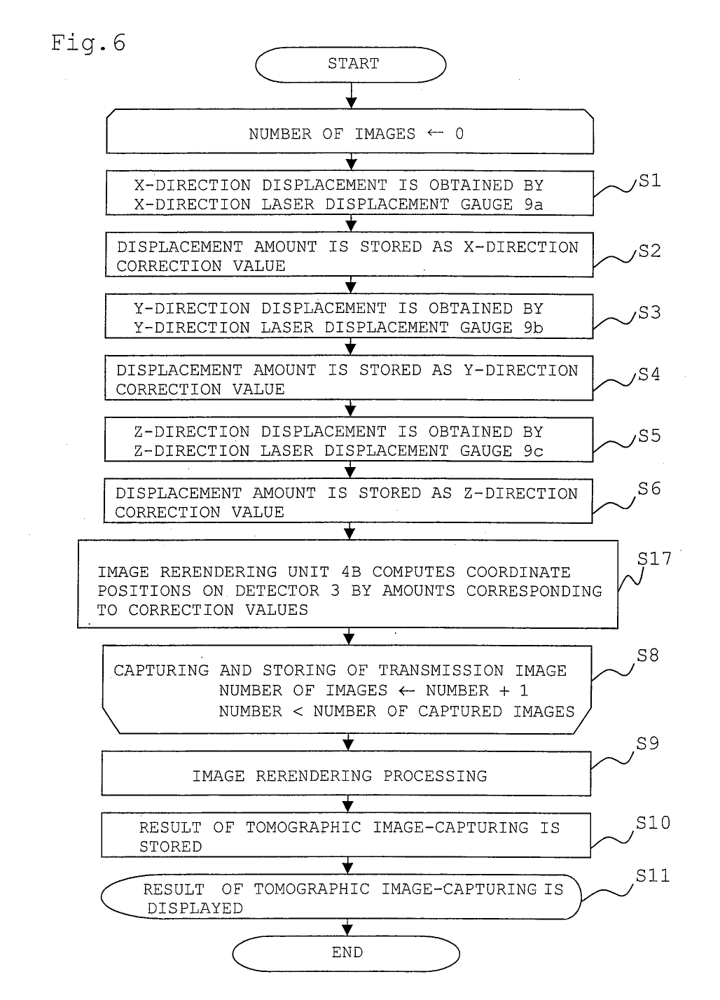

Embodiment 2 will be explained below with reference to a flowchart in FIG. 6. In Embodiment 2, setting of the initial condition and Steps S1 to S6 are the same as those in Embodiment 1. However, as the initial condition, it is further required that the positional relationships among the X-ray radiant unit 1, the table 2, and the detector 3 are stored as the x-direction, y-direction, and z-direction coordinate values, and in each of Steps S1, S3, and S5, it is confirmed that, when the displacement amount is measured, the positional relationships among the X-ray radiant unit 1, the table 2, and the detector 3 (the respective portions excluding the front end of the X-ray radiant unit 1) are the same as those under the initial condition.

Next, in Step S17, the image rerendering unit 4d obtains correction values Δx, Δy, and Δz from the correction value computation unit 4c and based on the correction values, computes to correct positions of the coordinate origin that is supposed to be located on the detection plane of the detector 3. Specifically, the computation is performed as follows.

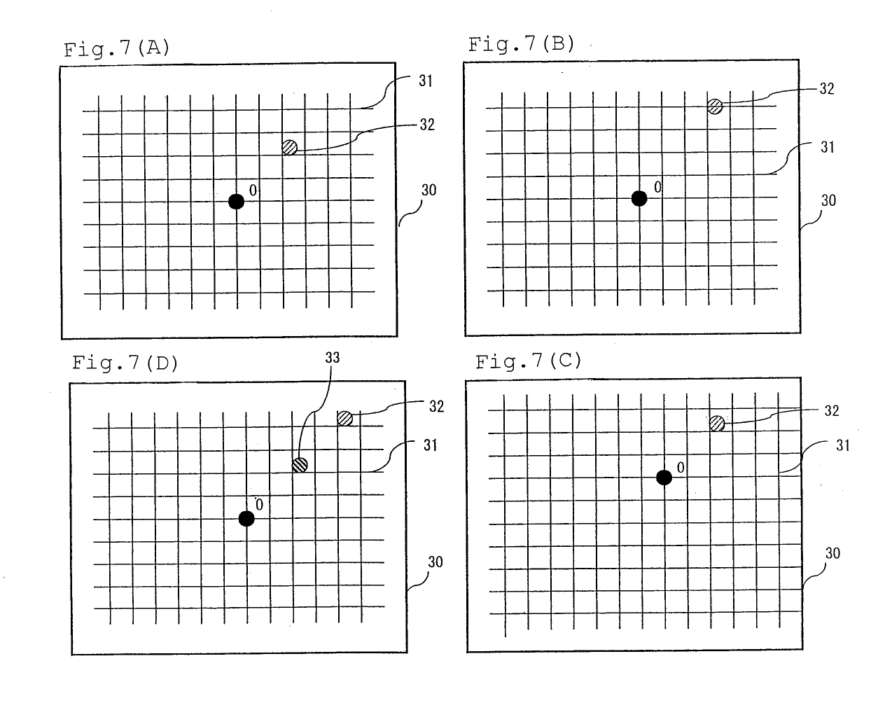

As illustrated in FIG. 7(A), in the case where the positional relationships among the radiation source inside the X-ray radiant unit 1, the table 2, and the detector 3 are in the initial condition, a detection position 32, on a detection plane 30 of the detector 3, of an imaging subject is located on a coordinate system 31 set on the detection plane 30. However, when a radiation-source shift is produced, the detection position 32 travels within the detection plane 30, as illustrated in FIG. 7(B), and the distance between the detection position 32 and the coordinate origin O also changes.

In contrast, in Step S17, by shifting the coordinate origin O by adding Δx, Δy, and Δz as predetermined amounts, the whole coordinate system is shifted on the detection plane 30. As a result, as illustrated in FIG. 7(C), when viewed from the coordinate origin O, the detection position 32 is corrected so as to be located in the same position as that in the case where image capturing is performed under the initial condition, i.e., in the case where image capturing is performed when no radiation-source shift is produced.

Next, when, in Step S8, by, through the image-capturing controller 5, controlling the X-ray radiant unit 1 and the detector 3, a transmission image is captured, the transmission image is formed at a corrected coordinate position on the detector 3; therefore, a captured image can be obtained that is located at the same coordinates as those of the image to be captured under the initial condition.

In addition, processing may be implemented in which the correction in Step S17 is omitted, and instead of shifting the coordinate origin O, Δx, Δy, and Δz are subtracted as predetermined amounts, as illustrated in FIG. 7(D), from the x-axis, y-axis, and z-axis positions, respectively, of the detection position 32 to treat it as a corrected detection position 33 when image capturing in Step S8 is performed. In this case, when viewed from the coordinate origin O, the coordinates of the corrected detection position 33 coincides with those of the detection position 32, viewed from the coordinate origin O, that is in the initial condition.

As discussed heretofore, according to Embodiment 2, by measuring the physical displacement amount of the front end of the X-ray radiant unit 1, and utilizing the obtained physical displacement amount and the positional relationships, under the initial condition, among the X-ray radiant unit 1, the table 2, and the detector 3, a radiation-source shift represented as data can be corrected before or after image capturing by the detector 3. Accordingly, by accurately anticipating change in the radiation-source position, a clear and high-resolution tomographic image can be obtained that has no blur such as an aliasing or an artifact. Moreover, the correction can be performed by means of software; therefore, Embodiment 2 has an advantage in that, by omitting the operation and the processing of moving the table and the detector only for the purpose of correction, the operation of the apparatus can be simplified.

In FIGS. 7(A) to 7(D), an x-y coordinate system is utilized as a coordinate system 31 for simplicity; however, in the case where z-direction correction is involved, the radiation-source shift and the effect of correction, as described later, appear as dimensional changes in an image at the detection position 32.

In the foregoing configuration, an X-ray CT apparatus that generates a 3-dimensional image has been utilized as an example, and it has been explained that, in order to obtain 3-dimensional coordinates, correction is performed in the x-, y-, and z-directions; however, in a correction apparatus and a correction method according to the present invention, it is not necessarily required to perform correction in all the three directions; thus, correction may be performed only in any one or two of the three directions.

For example, in the case where a configuration is employed in which only a z-direction physical displacement amount is detected and corrected, the configuration has the following advantage. In other words, generally, the foregoing radiation-source shift in a direction along the line that connects the X-ray source with the detector causes a blur or the like of the imaging-subject outline in a tomographic image and considerably affects the magnification ratio for a radiation image to be image-captured, in particular; however, all the exemplified conventional radiation-source correction methods are each to disclose only the position correction on a plane the normal to which is the line that connects the radiation-source with the detector, and there has not been any method to cope with the radiation-source shift in a direction along the line that connects the X-ray source with the detector. According to the present invention, by performing correction in the z-direction as the projection of the radiation-source shift in a direction along the line that connects the X-ray source with the detector, an appropriate focal position in accordance with the magnification ratio for an image to be image-captured can be ensured.

In particular, in the case where, as in foregoing embodiments, the positional relationships of the X-ray radiant unit 1, the imaging subject 10 placed on the table 2, and the detector 3 are not in coaxial (the cylindrical rotation axel of the X-ray radiant unit 1) relationships with one another, as illustrated in FIG. 1, two-dimensional displacement on a plane (a plane perpendicular to the rotation axel) is also produced, whereby the accuracy and the resolution are considerably affected. The effect appears conspicuously, especially in the case where, in order to ensure a high magnification rate, the distance between the X-ray source and an imaging subject is made short and the distance between the detector and the imaging subject is made long. Accordingly, the present invention that enables the z-direction correction is advantageous to such a configuration for CT-scanning as Embodiment 2.

In the case where the X-ray radiant unit 1, an imaging subject placed on the table 2, and the detector 3 are arranged in such a way as to image-capture the imaging subject fixed coaxially with the rotation axel, correction may be performed only along the x-direction and the y-direction.

Additionally, in the foregoing configuration, the relative positional relationships among the X-ray radiant unit 1, the table 2, and the detector 3 are utilized for performing correction; the positional relationships are ensured by the assumption that the electron-beam collision position P inside the X-ray radiant unit 1 is constant (the change in the contour of the X-ray radiant unit 1 corresponds to the change in the collision position P, on a one-to-one basis), the detection plane is fixed on the detector 3, and the imaging subject 10 is placed on the table 2, while the shape thereof is kept constant. Among the relationships, the artificial manipulation during correction and image capturing affects the relationship between the table 2 and the imaging subject; therefore, it is desirable to place the imaging subject on the table 2 in such a way as not to be deformed and displaced, under the initial condition, during correction, and during image capturing.

After the physical displacement amount of the X-ray radiant unit 1 is detected, a configuration is employed in which, as described in Embodiment 1, a position correction unit is provided that moves the X-ray radiant unit 1, that moves the table 2 and the detector 3, or that moves the X-ray radiant unit 1, the table 2, and the detector 3 so that the relative positional relationships among the X-ray radiant unit 1, the table 2, and the detector 3 can maintain the reference condition; or a configuration is employed in which, as described in Embodiment 2, a data correction unit is provided that performs correction through software, prior to or during image capturing by the detector 3; however, a configuration may be employed in which both the position correction unit and the data correction unit are provided. In this case, by, based on the physical displacement amount, distributing and allocating correction values to the position correction unit and the data correction unit, thereby making the both correction units operate, it is made possible that, even though a radiation-source shift is produced, an X-ray image is obtained that is rendered on the same coordinates as those of the image obtained by being image-captured under the initial condition.

In the case where, for example, a large radiation-source shift is produced that makes it impossible that, only by mechanical movement of the X-ray radiant unit 1, the table 2, and the detector 3 through the position correction unit, the relative positional relationships in a condition under which no correction is required is maintained, the configuration having the position correction unit and the data correction unit can be utilized with correction through software as a supplementary means, software; therefore, that configuration is effective when there is restriction on the shape and the size of a radiation image capturing apparatus and the like.

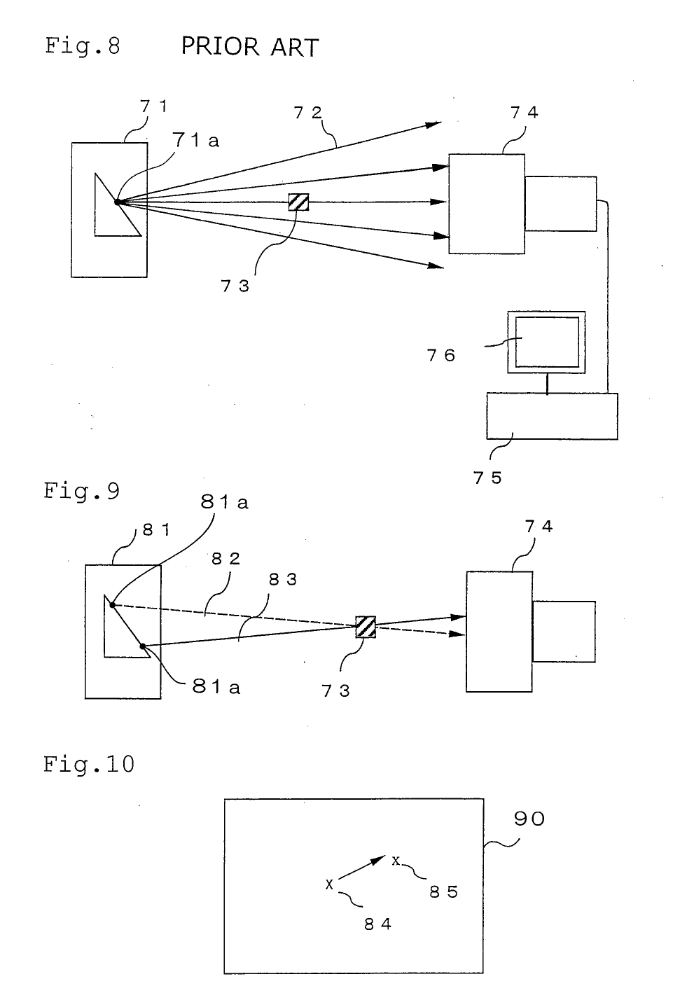

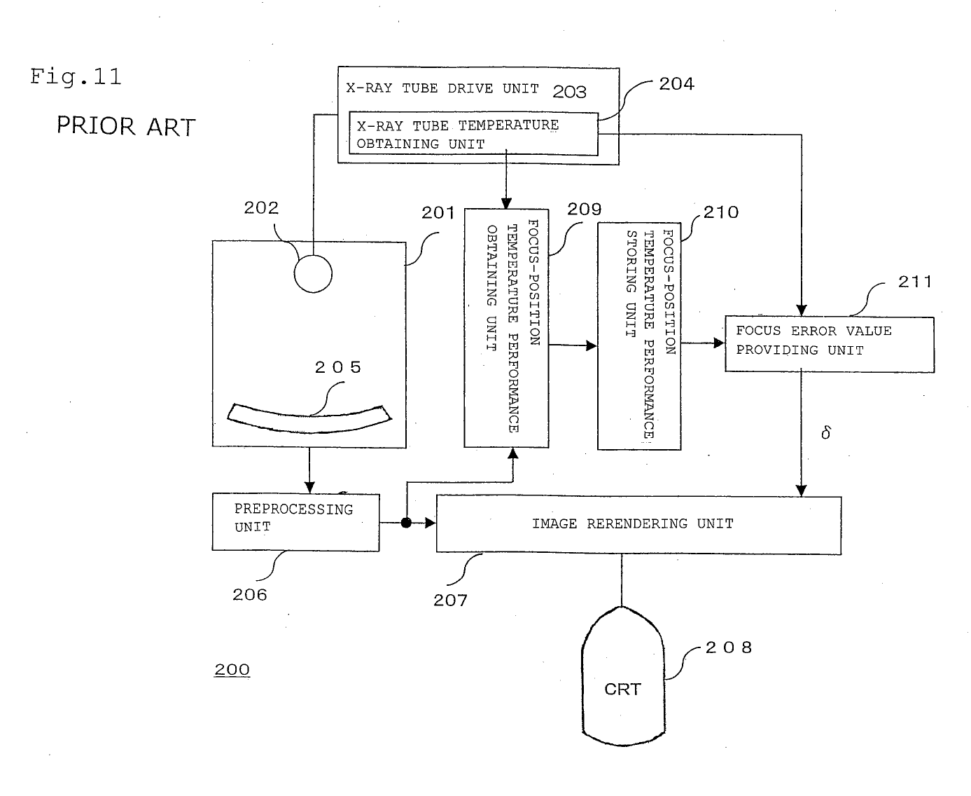

In addition, in the foregoing embodiments, it has been explained that the radiation image capturing condition correction apparatus according to the present invention is incorporated in an X-ray CT apparatus as an example of a radiation image capturing apparatus; however, the correction apparatus can be utilized not only in the image capturing apparatuses illustrated in FIGS. 8 and 12 but also in other apparatuses, i.e., regardless of the kinds of apparatuses, as long as they are apparatuses that each perform image capturing, of a radiation image by transmitting radiations, that is not limited to the kinds of image capturing, such as three-dimensional image capturing and two-dimensional capturing. Moreover, the correction apparatus may be incorporated in an image capturing apparatus that utilizes as a radiation an α-ray, a β-ray, a γ-ray, or a heavy-ion ray, instead of an x-ray.

Still moreover, a radiation image capturing condition correction apparatus according to the present invention may not preliminarily be integrated with a radiation image capturing apparatus, but may be utilized as a separated apparatus, in combination with an existing radiation image capturing apparatus. In particular, the correction apparatus according to Embodiment 2 performs correction through software; therefore, it has an advantage in weight saving and universality.

Additionally, a program according to the present invention makes a computer perform functions of all or part of the units (or devices, elements, circuits, units, and the like) of the foregoing radiation image capturing condition correction apparatus according to the present invention; the program may operate in collaboration with a computer.

Additionally, the present invention provides a medium that carries a program for making a computer perform functions of all or part of the units of the foregoing radiation image capturing condition correction apparatus according to the present invention; a medium may be employed that can be read by a computer and the program read out of which by the computer performs the foregoing functions in collaboration with the computer.

In addition, the foregoing term “part of the units” according to the present invention signifies some units among the units or part of the functions of a single unit.

Additionally, a storage medium in which a program according to the present invention is stored and that can be read by a computer is included in the present invention.

Moreover, one of the utilization forms for a program according to the present invention may be a mode in which a program is stored in a storage medium that can be read by a computer and the program operates in collaboration with the computer.

Still moreover, one of the utilization forms for a program according to the present invention may be a mode in which a program is transmitted through a transmission medium, read by a computer, and operates in collaboration with the computer.

The storage medium also includes a ROM.

The foregoing computer according to the present invention is not limited to a computer that includes a pure hardware such as a CPU, but may be a computer that includes firmware, an OS, or a peripheral device.

As explained heretofore, a configuration according to the present invention may be realized through software or through hardware.

The present invention demonstrates an effect with which, in capturing a radiation image, high-accuracy correction for a radiation-source shift is readily realized, whereby the present invention is useful for a radiation image capturing condition correction apparatus and the like; for example, in capturing a radiation image, the present invention enables a high-magnification and high-resolution tomographic image with reduced aliasings and artifacts to be obtained, whereby the present invention can be applied to an X-ray CT apparatus, a tomography apparatus, and the like.

What is claimed is:

1. A radiation image capturing condition correction apparatus for use with a) an image-capturing unit which captures a radiation image of a predetermined imaging subject; and b) a radiation generating unit which generates radiation, said radiation image capturing condition correction apparatus comprising:
a measuring unit which measures an amount of physical displacement of said radiation generating unit; and
a position correction unit for generating a correction value which is used for correcting a position at which said image-capturing unit captures said radiation image.

2. The radiation image capturing condition correction apparatus according to claim 1, wherein, the position correction unit, based on the generated correction value, performs correction in such a way that the relative positional relationships, among the radiation generating unit, the predetermined imaging subject, and the image-capturing unit, which exist when the radiation generating unit is at the predetermined position is maintained.

3. The radiation image capturing condition correction apparatus according to claim 2, wherein, as the correction, the position correction unit moves the radiation generating unit.

4. The radiation image capturing condition correction apparatus according to claim 2, wherein, as the correction, the position correction unit moves the imaging subject and the image-capturing unit.

5. The radiation image capturing condition correction apparatus according to claim 2, wherein, as the correction, the position correction unit moves each of the radiation generating unit, the imaging subject, and the image-capturing unit.

6. The radiation image capturing condition correction apparatus according to claim 2, wherein, as the correction, the position correction unit returns the radiation generating unit to the predetermined position.

7. The radiation image capturing condition correction apparatus according to claim 2, wherein the one direction is a direction along a line perpendicular to an image capturing plane for the radiation image and the position correction unit performs correction operation in the one direction.

8. The radiation image capturing condition correction apparatus according to claim 7, wherein the physical displacement amount is measured in one direction or in two directions, which are perpendicular to each other, on the image capturing plane, and the position correction unit performs correction operation in the one direction or in the two directions.

9. The radiation image capturing condition correction apparatus according to claim 1, wherein, as the radiation, any one of an X-ray, an α-ray, a β-ray, a γ-ray, and a heavy-ion ray is utilized.

10. A radiation image capturing apparatus comprising:
a radiation generating unit which generates radiations;
an imaging subject arrangement unit on which a predetermined imaging subject is arranged;
an image-capturing unit having an image capturing plane on which a radiation image, which is image-captured by means of the radiations, of the imaging subject is formed; and
the radiation image capturing condition correction apparatus according to claim 1.

11. A radiation image capturing condition correction apparatus comprising:
a measuring unit which, in capturing on an image-capturing unit a radiation image of a predetermined imaging subject, measures an amount of physical displacement, of a radiation generating unit which generates radiations, from a predetermined position in at least one direction; and
a data correction unit which corrects data on the radiation image, based on the physical displacement amount and the relative positional relationships, among the radiation generating unit, the imaging subject, and the image-capturing unit, at the moment when the radiation generating unit has been at the predetermined position.

12. The radiation image capturing condition correction apparatus according to claim 11, wherein the data correction unit utilizes, as the data on the radiation image, a predetermined amount corresponding to the physical displacement amount and performs correction in which the position of a coordinate origin defined on a detection plane of the image-capturing unit is moved by the predetermined amount.

13. The radiation image capturing condition correction apparatus according to claim 11, wherein the data correction unit utilizes, as the data on the radiation image, a predetermined amount corresponding to the physical displacement amount and performs correction in which a detection position of the imaging subject on a detection plane of the image-capturing unit is moved by the predetermined amount.

14. The radiation image capturing condition correction apparatus according to claim 11, wherein the one direction is a direction along a line perpendicular to an image capturing plane for the radiation image and the data correction unit performs correction operation in the one direction.

15. The radiation image capturing condition correction apparatus according to claim 14, wherein the physical displacement amount is measured in one direction or in two directions, which are perpendicular to each other, on the image capturing plane, and the data correction unit performs correction operation in the one direction or in the two directions.

16. The radiation image capturing condition correction apparatus according to claim 11, wherein, as the radiation, any one of an X-ray, an α-ray, a β-ray, a γ-ray, and a heavy-ion ray is utilized.

17. A radiation image capturing apparatus comprising:
a radiation generating unit which generates radiations;
an imaging subject arrangement unit on which a predetermined imaging subject is arranged;
an image-capturing unit having an image capturing plane on which a radiation image, which is image-captured by means of the radiations, of the imaging subject is formed; and
the radiation image capturing condition correction apparatus according to claim 11.

18. A radiation image capturing condition correction method for use with a) an image-capturing unit which captures a radiation image of a predetermined imaging subject; and b) a radiation generating unit which generates radiation, said radiation image capturing condition correction apparatus, comprising:
measuring an amount of physical displacement of said radiation generating unit; and
generating a correction value which is used for correcting a position at which said image-capturing unit captures said radiation image.

19. The radiation image capturing condition correction method according to claim 18, further comprising, performing correction, based on the generated correction value, in such a way that the relative positional relationships, among the radiation generating unit, the predetermined imaging subject, and the image-capturing unit, which exist when the radiation generating unit is at the predetermined position is maintained.

20. The radiation image capturing condition correction method according to claim 18, wherein, as the radiation, any one of an X-ray, an α-ray, a β-ray, a γ-ray, and a heavy-ion ray is utilized.

21. A radiation image capturing condition correction method comprising:
measuring an amount of physical displacement of a radiation generating unit which generates radiations, from a predetermined position in at least one direction, in capturing on an image-capturing unit a radiation image of a predetermined imaging subject; and
correcting data on the radiation image, based on the physical displacement amount and the relative positional relationships, among the radiation generating unit, the imaging subject, and the image-capturing unit, at the moment when the radiation generating unit has been at the predetermined position.

22. The radiation image capturing condition correction method according to claim 21, wherein, as the radiation, any one of an X-ray, an α-ray, a β-ray, a γ-ray, and a heavy-ion ray is utilized.

23. A computer-processable storage medium in which a program is stored, the program making a computer function as a data correction unit, of the radiation image capturing condition correction apparatus according to claim 11, that corrects data on the radiation image, based on the physical displacement amount and the relative positional relationships, among the radiation generating unit, the imaging subject, and the image-capturing unit, at the moment when the radiation generating unit has been at the predetermined position.
